(19) United States
(12) Patent Application Publication
(10) Pub. No.: US 2005/0221530 A1
(43) Pub. Date: Oct. 6, 2005

(54) Method for enhancing electrical characteristics of organic electronic devices

(75) Inventors: Hsiang-Yuan Cheng, Taipei (TW); Jia-Chong Ho, Yinge Town (TW); Wen-Kuei Huang, Chiayi City (TW)

Correspondence Address: BRUCE H. TROXELL, SUITE 1404, 5205 LEESBURG PIKE, FALLS CHURCH, VA, 22041, US

(73) Assignee: Industrial Technology Research institute

(21) Appl. No.: 10/879,168

(22) Filed: Jun. 30, 2004

(30) Foreign Application Priority Data
Apr. 5, 2004 (TW) 93112454

(51) Int. Cl. H01L 21/00

(52) U.S. Cl. 438/82

(57) ABSTRACT

The present invention provides a method for enhancing electrical characteristics of organic electronic devices, especially for an organic thin-film transistors, comprising the steps of: providing a substrate with a gate and an insulator layer formed thereon; preparing an organic solution by mixing materials of an organic semiconductor polymer, an organic insulator polymer, a conducting particle and a solvent; forming an organic semiconductor layer on top of the insulator layer between the source and the drain using the organic solvent. Wherein, the organic semiconductor polymer can be a polymer selected from the group consisting of poly(3-alkylthiophene) (P3AT) with different alkyl side groups of 2, 4, 6, 8, 10, 12, and 18, as the P3HT is a P3AT with alkyl side group of 6, and the organic insulator polymer can be a polymer selected from the group consisting of poly(methylmethacrylate) (PMMA), and polybutylene terephthalate (PBT), etc. and the conducting particle can be a kind of particle selected from the group consisting of carbon nanotubes (CNTs), C₆₀, and nano silver particle, and so on, and the solvent can be a solvent selected from the group consisting of xylene, toluene, and THF, and so forth.

### FIELD OF THE INVENTION

The present invention relates to a method for enhancing electrical characteristics of organic electronic devices, and more particularly, to a method for enhancing electrical characteristics of organic thin-film transistors by improving the physical properties of the organic semiconductors.

### BACKGROUND OF THE INVENTION

Organic semiconductors have been studied since the late 1940s, and the field effect thereof was first provided at 1970. However, not until 1987 that the organic field-effect transistor (OFET) was proven by Koezuka, et al. to be an electronic device with great potential. OFETs can be referred as the organic thin-film transistors (OTFT) for adopting the structure of thin-film transistors (TFTs). OTFTs provide two principle advantages over thin film transistors based on inorganic semiconductors—they can be fabricated at lower temperature and, potentially, at significantly lower cost. Moreover, Optimized OTFTs now show electronic characteristics approaching or exceeding those of hydrogenated amorphous silicon TFTs. Low process temperature in particular may allow OTFTs to be integrated on inexpensive plastic substrates, rather than glass. The prospect of flexible, unbreakable, extremely low-weight flat panel displays at relatively low cost has spurred a number of manufacturers to consider using the same on low-cost large-area electronic products for a variety of military, medical, industrial, and consumer applications, such as active-matrix displays, smart cards, price tags, inventory tags, and large-area sensor arrays.

In such OTFTs most organic semiconductors, like poly(thienylene vinylene) (PTV), regio-regular poly(3-hexylthiophene) (rr-P3HT) and pentacene allow a significant current to flow between source and drain in the accumulation layer, when a voltage is applied to the gate. There are two OTFT device configurations, that is, the top-contact device, in which the source and drain contacts were defined using a shadow mask following the deposition of the organic semiconductor layer, and the bottom-contact device, in which the source and drain contacts were defined by photolithography prior to depositing the organic semiconductor layer. The materials used for forming the organic semiconductor layer include small-molecules, oligomers and conjugated polymers. The polymer organic semiconductor layer is formed by coating the solution of rr-P3HT dissolved in an organic solvent onto a substrate using a solution-processing method. Most of the prior methods for producing the organic semiconductor layer are at an experimental stage with unsatisfactory on-off ratio and use chloroform as the organic solvent which is a chemical forbidden by the industry.

In view of the above description, the conventional methods for producing organic TFT have at least the following disadvantages:
(1) The OTFTs will be impractical if the on-off ratio is low.
(2) Although, the processing of small-molecule or oligomer organic semiconductors is fast and simple comparing with that of the amorphous silicon TFTs, the vacuum equipments are required for the process that will increase the manufacturing cost.
(3) The use of chloroform is neither conforming to the industrial standard, nor environmental safe that will affect the possibility of mass-production and thus low the interesting of further research.

### SUMMARY OF THE INVENTION

The primary object of the invention is to provide a method for enhancing electrical characteristics of organic electronic devices, which is capable of the on-off ratio of the organic thin-film transistors.

The secondary object of the invention is to provide a method for enhancing electrical characteristics of organic electronic devices, which not only can be realized by a simple and fast manufacturing process, but also can do without vacuum equipments such that the manufacturing cost is reduced.

Another object of the present invention is to provide a method for enhancing electrical characteristics of organic electronic devices, which is conformed with the current industrial standard while it is environmental friendly.

To achieve the aforementioned objects, the present invention provides a method for enhancing electrical characteristics of organic electronic devices, especially for an organic thin-film transistors, comprising the steps of: providing a substrate with a gate, an insulator layer, a source and a drain formed thereon; preparing an organic solution by mixing materials of an organic semiconductor polymer, an organic insulator polymer, a conducting particle and a solvent; forming an organic semiconductor layer on top of the insulator layer between the source and the drain using the organic solution.

Wherein, the organic semiconductor polymer can be a polymer selected from the group consisting of poly(3-alkylthiophene) (P3AT) with different alkyl side groups of 2, 4, 6, 8, 10, 12, and 18, as the P3HT is a P3AT with alkyl side group of 6, and the organic insulator polymer can be a polymer selected from the group consisting of poly(methylmethacrylate) (PMMA), and polybutylene terephthalate (PBT), etc. and the conducting particle can be a kind of particle selected from the group consisting of carbon nanotubes (CNTs), C₆₀, and nano silver particle, and so on, and the solvent can be a solvent selected from the group consisting of xylene, toluene, and THF, and so forth.

### BRIEF DESCRIPTION OF THE DRAWINGS

FIG. 1 is a schematic diagram of an organic thin-film transistor according to a preferred embodiment of the present invention.

FIG. 2A is an output characteristic curve of a pure rr-P3HT organic thin-film transistor.

FIG. 2B is an output characteristic curve of an rr-P3HT/PMMA organic thin-film transistor.

FIG. 3A is an output characteristic curve of a CNT/rr-P3HT/PMMA organic thin-film transistor.

FIG. 3B is a conversion characteristic curve of a CNT/rr-P3HT/PMMA organic thin-film transistor.

### DESCRIPTION OF THE PREFERRED EMBODIMENT

With the following descriptions and drawings, the objects, features, and advantages of the present invention can be better interpreted.

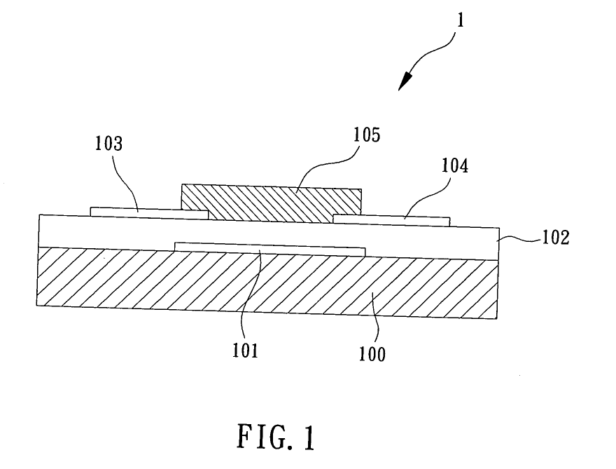

Please refer to FIG. 1, which is a schematic diagram of an organic thin-film transistor according to a preferred embodiment of the present invention. After a gate 101 is form on a substrate 100, an insulator layer 102 is formed using an organic insulator or an inorganic insulator with a source 103, a drain 104 and an organic semiconductor layer 105 further evaporated onto the insulator layer 102 between the source 103 and the drain 104 such that an organic thin-film transistor 1 is formed. A material selected from the group consisting of silicon wafer, glass substrate, metal substrate, plastic substrate, and so on, can be used as the substrate 100. A material selected from the group consisting of metal, organic conducting polymer and indium tin oxide (ITO), etc., can be used for the gate 101, the source 103 and the drain 104. The manufacturing processes adopted for forming the organic thin-film transistor 1 include: spin-coating, inkjet-printing, drop-printing, casting, micro-contact, micro-stamp, and so forth. In addition, the organic semiconductor layer 105 is formed using an organic solution, which is previously prepared using the method as described hereinafter: dissolving an organic semiconductor polymer, such as the rr-P3HT in a preferred embodiment of the present invention, in a solvent of xylene, toluene or TIE while mixing with an insulator polymer, such as PMMA and PBT, etc., and a small amount of conducting particles, such as CNTs, C₆₀ and nano silver particle, etc. In a preferred embodiment of the present invention, the organic solution is formed by dissolving rr-P3HT in xylene while mixing with PMMA and a small amount of CNTs, wherein Xylene/PMMA/rr-P3HT/CNT=94.6%/5.2%/0.17%/0.03%, and the gate 101 (˜1 kÅ) is formed by sputtering ITO on a glass substrate, and the insulator layer 102 (˜3 kÅ) is formed with a layer of SiO₂ using Plasma Enhanced Chemical Vapor Deposition (PECVD), and the source 103 (˜1 kÅ) and the drain 104 (˜1 kÅ) made of ITO is deposited onto the insulator layer 102 between the source and the drain by sputter deposition, and the organic semiconductor layer 105 is formed with the organic solution of rr-P3HT using the method of drop-printing.

Since the most suitable solvent, i.e. chloroform, is forbidden by the industry, the present invention adopts an inferior solvent, i.e. xylene. However, while mixing PMMA and a small amount of CNTs into the xylene, not only the electrical characteristics of the organic thin-film transistor 1 is enhanced by increase the on-off ratio to above 10⁴, but also the solvent used in the present invention is conformed with the industrial standard and environmental friendly.

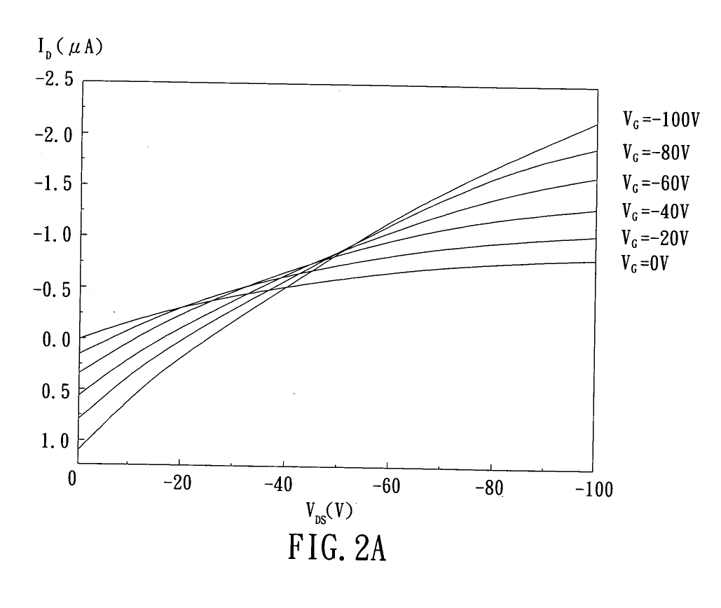

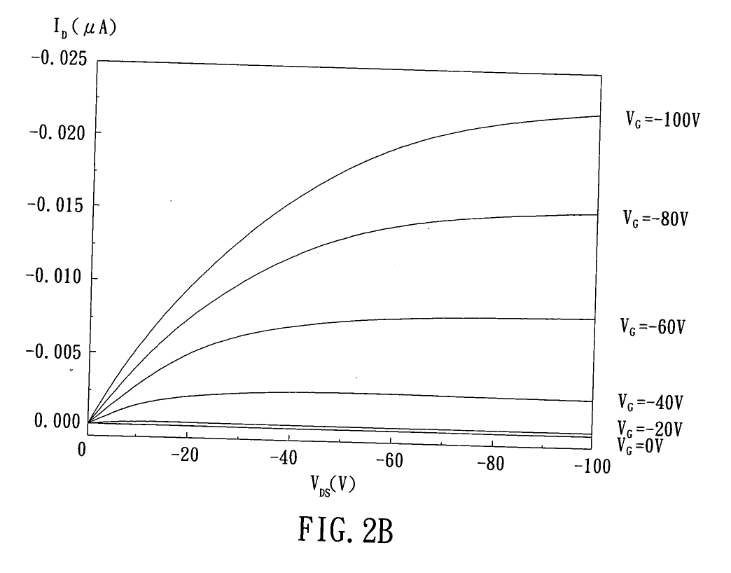

Please refer to FIG. 2A, which is an output characteristic curve of a pure rr-P3HT organic thin-film transistor. Since the rr-P3HT is normally “on”, i.e., a significant drain current, which can reach 10⁻⁷ A, flows at zero gate-source voltage, and the oxygen molecule and water molecule in the atmosphere will cause the rr-P3HT to have larger charge carrier mobility and better conductivity such that it is required to overcome a reverse current caused by the rr-P3HT mixing with water and oxygen along with the increasing of V_{G}, the on current and off current of the pure rr-P3HT organic thin-film transistor are respectively −2.17×10⁻⁶ A and −8.22×10⁻⁷ A enabling the on/off ratio thereof to be only 2.64. In this regard, the output electrical characteristic curve of FIG. 2A only shows linearity, which represents that the pure rr-P3HT organic thin-film transistor possesses poor electrical characteristics.

Please refer to FIG. 2B, which is an output characteristic curve of an rr-P3HT/PMMA organic thin-film transistor. The off current is reduced to −4.60×10⁻¹² A while the on current is only reduced slightly to −2.19×10⁻⁸ A after mixing the rr-P3HT with a certain amount of PMMA, since the mixing will elongate the chains of the rr-P3HT and the PMMA is capable isolating water and oxygen from the rr-P3HT for saving the same to be affect by them. Therefore, the on-off ratio of the rr-P3HT/PMMA organic thin-film transistor is increased to 4.76×10³. As seen in FIG. 2B, the electrical characteristic curve is the combination of the linear area and the saturated area, which is obvious, representing that the electrical characteristics of the rr-P3HT/PMMA organic thin-film transistor is being greatly enhanced comparing to that of FIG. 2A.

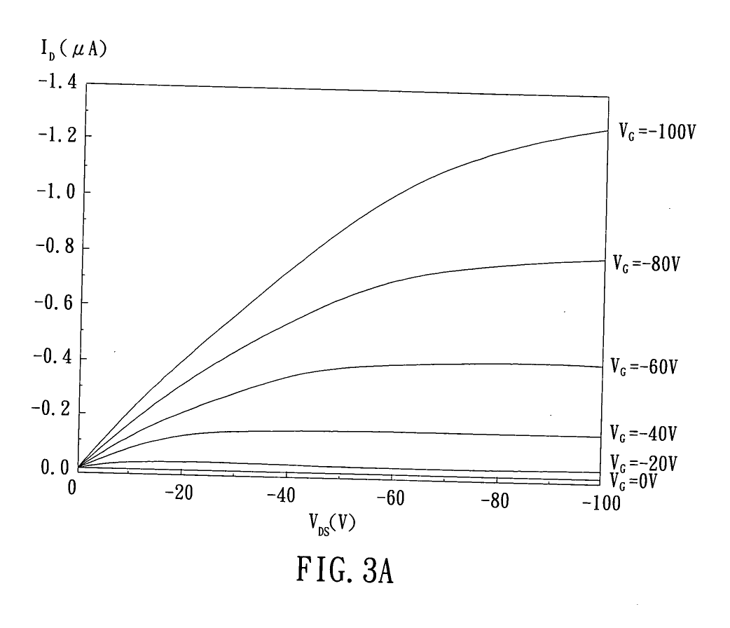

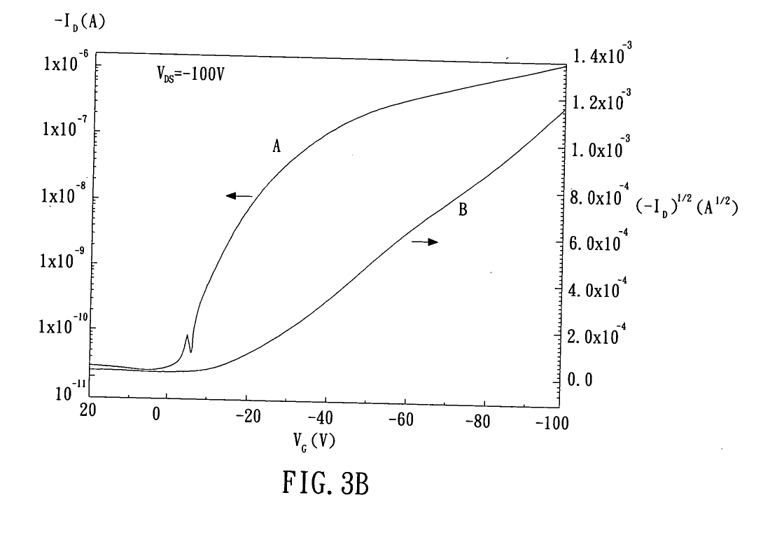

Please refer to FIG. 3A, which is an output characteristic curve of a CNT/rr-P3HT/PMMA organic thin-film transistor. In order to further improve the on current of the rr-P3HT/PMMA organic thin-film transistor, a small amount of CNT is added into the mixture for utilizing the conductivity of the CNT to raise the on current to −1.35×10⁻⁶ A while the off current only being increased slightly to −2.61×10⁻¹¹ A. Therefore, the on/off ratio of the CNT/rr-P3HT/PMMA organic thin-film transistor can jump to 5.17×10⁴. As seen in FIG. 3A, the electrical characteristic curve is also the combination of the linear area and the saturated area, which is obvious, representing that the electrical characteristics of the CNT/rr-P3HT/PMMA organic thin film transistor is being greatly enhanced comparing to that of FIG. 2B.

Please refer to FIG. 3B, which is a conversion characteristic curve of a CNT/rr-P3HT/PMMA organic thin-film transistor under V_{DS}=−100V. From the A curve of FIG. 3B, an −I_{D} value while V_{G}=0 and an −I_{D} while V_{G}=−100V can be acquired with respect to the left coordinate, i.e., respectively the off current and the on current of the CNT/rr-P3HT/PMMA organic thin-film transistor, such that the on-off ratio of the CNT/rr-P3HT/PMMA organic thin-film transistor can be computed. From the B curve of FIG. 3 with respect to the right coordinate, the slope of the B curve can be extracted so as to acquire the carrier mobility of the CNT/rr-P3HT/PMMA organic thin-film transistor, which is known to those skilled in the art and is not described hereinafter.

To sum up, the method for enhancing electrical characteristics of organic electronic devices of the present invention is capable of effectively increase the on-off ratio of the organic thin-film transistors, and is cost saving while no vacuum equipment is required and having a fast and simple manufacturing process. In addition, the present invention is conformed to current industrial standard and also environmental friendly. These preferred embodiments are however not the limited scope of the present invention. For examples: production methods of optional thin films with different materials, different kinds of conducting particles and solvent, to change the add step from mixed materials, different heating temperatures, and etc.. Any appropriate and small variation and adjustment based on the appended claims that still possess the merit of the present invention should be considered within the scope and the spirit of the present invention.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments, which do not depart from the spirit and scope of the invention.

1. A method for enhancing electrical characteristics of an organic electronic device, being used for enhancing electrical characteristics of an organic thin-film transistor, comprising the steps of:
providing a substrate with a gate and an insulator layer formed thereon;
preparing an organic solution by mixing materials of an organic semiconductor polymer, an organic insulator polymer, a conducting particle and a solvent; and
forming an organic semiconductor layer on top of the insulator layer between the source and the drain using the organic solution.

2. The method of claim 1, wherein a drain and a source is further being formed on the insulator lalyer.

3. The method of claim 1, wherein the organic semiconductor polymer is selected from the group of poly(3-alkylthiophene) (P3AT).

4. The method of claim 1, wherein the organic insulator polymer is a polymer selected from the group consisting of poly(methylmethacrylate) (PMMA), and polybutylene terephthalate (PBT).

5. The method of claim 1, wherein the conducting particle is particular selected from the group consisting of carbon nanotubes (CNTs), C₆₀, and nano silver particle.

6. The method of claim 1, wherein the solvent is a solvent selected from the group consisting of xylene, toluene, and THF.

7. The method of claim 1, wherein the process used for forming the organic semiconductor layer on top of the insulator layer between the source and the drain using the organic solution is a process selected from the group consisting of spin-coating, inkjet-printing, drop-printing, casting, micro-contact and micro-stamp.

8. The method of claim 1, wherein the substrate is the one selected from the group consisting silicon wafer, glass substrate, metal substrate and plastic substrate.

9. The method of claim 1, wherein the gate, the drain and the source are made of a material selected from the group consisting of metal, organic conducting polymer and ITO.

10. The method of claim 1, wherein the insulator layer is made of a material selected from the group consisting of organic insulators and inorganic insulators.

11. The method of claim 1, wherein the on-off ratio of the organic thin-film transistors is at least 10⁴.
